(19) United States
(12) Patent Application Publication
(10) Pub. No.: US 2024/0142936 A1
(43) Pub. Date: May 2, 2024

(54) ANOMALY DETECTION METHOD, ELECTRONIC DEVICE, NON-TRANSITORY COMPUTER-READABLE STORAGE MEDIUM, AND COMPUTER PROGRAM

(71) Applicant: SEMES CO., LTD., Chungcheongnam-do (KR)

(72) Inventor: Dong Hyun Jun, Gyeonggi-do (KR)

(21) Appl. No.: 18/105,739

(22) Filed: Feb. 3, 2023

(30) Foreign Application Priority Data
Oct. 31, 2022 (KR) 10-2022-0143202

(51) Int. Cl. G05B 19/406; G05B 13/02

(52) U.S. Cl. CPC G05B 19/406; G05B 13/0265; G05B 2219/45031

(57) ABSTRACT

An anomaly detection method capable of minimizing the consumption of computing resources and time is provided. The anomaly detection method includes: learning a first classifier, which includes an encoder and a decoder, using a plurality of training data, which are classified into a plurality of first subsets; extracting features from the plurality of training data by computing the plurality of training data with the encoder of the learned first classifier; reconstructing the plurality of training data into a plurality of second subsets by clustering the plurality of training data based on the extracted features; learning a plurality of second classifiers, which correspond to the plurality of second subsets, using the second subsets; and detecting any abnormality in input data using the plurality of second classifiers.

### CROSS-REFERENCE TO RELATED APPLICATION

This application claims priority from Korean Patent Application No. 10-2022-0143202 filed on Oct. 31, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to an anomaly detection method, an electronic device, a non-transitory computer-readable storage medium, and a computer program.

### 2. Description of the Related Art

Semiconductor fabrication processes may be performed one after another in semiconductor fabrication equipment and may be classified into preprocesses and postprocesses. The semiconductor fabrication equipment may be installed in space called “Fab”.

The preprocesses refer to processes of forming chips by forming circuit patterns on a wafer. The preprocesses may include a deposition process of forming a thin film on a wafer, a photolithography process of transferring photoresist on the thin film with the use of a photomask, an etching process of selectively removing any unnecessary parts with the use of chemicals or reactive gases to form desired circuit patterns on the wafer, an ashing process of removing parts of the photoresist that remain unetched, an ion implantation process of injecting ions into parts connected to the circuit patterns to impart the characteristics of an electronic device, and a cleaning process of removing any contaminant from above the wafer.

The postprocesses refer to processes of evaluating the performance of products obtained by the preprocesses. The postprocesses may include a primary inspection process of inspecting whether chips on a wafer operate properly and detecting good and bad products, a packaging process of cutting and separating the chips via dicing, die bonding, wire bonding, molding, and marking, and a final inspection process of finally inspecting the characteristics and reliability of the products via an electrical property test and a burn-in test.

A variety of facilities are used during the semiconductor fabrication processes, and the development of various diagnostic models is underway to diagnose normal or abnormal conditions of each of the facilities.

If the diagnostic models are created and used for recipes of each of the facilities, as many diagnostic models as there are recipes need to be created and require a considerable amount of computing resources and time for artificial intelligence learning. Also, whenever the recipes change during mass production, their respective diagnostic models need to be called up, and there are difficulties in operation and management, such as relearning the diagnostic models and distributing them to various facilities. Also, defects may not be able to be properly detected from new recipes or recipes with insufficient data because these recipes may not be able to be properly determined until sufficient amount of data for learning is accumulated.

### SUMMARY

Aspects of the present disclosure provide an anomaly detection method capable of minimizing the consumption of computing resources and time.

Aspects of the present disclosure also provide an electronic device, a non-transitory computer-readable storage medium, and a computer program for performing the anomaly detection method.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, an anomaly detection method includes: learning a first classifier, which includes an encoder and a decoder, using a plurality of training data, which are classified into a plurality of first subsets; extracting features from the plurality of training data by computing the plurality of training data with the encoder of the learned first classifier; reconstructing the plurality of training data into a plurality of second subsets by clustering the plurality of training data based on the extracted features; learning a plurality of second classifiers, which correspond to the plurality of second subsets, using the second subsets; and detecting any abnormality in input data using the plurality of second classifiers.

According to another aspect of the present disclosure, an anomaly detection method includes: learning a classifier, which includes an encoder and a decoder, using a training data set, which includes a plurality of training data subsets; extracting features for each training data of the training data set by computing each training data of the training data set with the encoder of the learned classifier; reconstructing the training data subsets by clustering the extracted features based on locations of the extracted features in feature space and clustering each training data of the training data set based on the clustered features; creating a plurality of relearned classifiers by relearning the learned classifier with the use of the reconstructed training data subsets; and detecting any abnormality in input data using the plurality of relearned classifiers.

According to another aspect of the present disclosure, an electronic device includes: a processor; and a memory connected to the processor. The memory stores instructions that can be executed by the processor, and the instructions are executed by the processor to execute the anomaly detection method.

According to another aspect of the present disclosure, a computer program is for performing the steps of: learning a first classifier, which includes an encoder and a decoder, using a plurality of training data, which are classified into a plurality of first subsets; extracting features from the plurality of training data by computing the plurality of training data with the encoder of the learned first classifier; reconstructing the plurality of training data into a plurality of second subsets by clustering the plurality of training data based on the extracted features; learning a plurality of second classifiers, which correspond to the plurality of second subsets, using the second subsets; and detecting any abnormality in input data using the plurality of second classifiers.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram of a semiconductor equipment diagnostic device according to an embodiment of the present disclosure;

FIG. 2 is a block diagram of a classifier included in a control unit of FIG. 1;

FIG. 3 is a flowchart illustrating a semiconductor equipment diagnostic method using the semiconductor equipment diagnostic apparatus according to an embodiment of the present disclosure;

FIG. 4 illustrates data and a recipe processed by the semiconductor equipment diagnostic method of FIG. 3;

FIG. 5 illustrates how to input data in the semiconductor equipment diagnostic method of FIG. 3;

FIG. 6 illustrates how to cluster data in the semiconductor equipment diagnostic method of FIG. 3; and

FIG. 7 illustrates how to process clustered data in the semiconductor equipment diagnostic method of FIG. 3.

### DETAILED DESCRIPTION

Preferred embodiments of the present disclosure will be described in detail with reference to the accompanying drawings. The present disclosure and methods of accomplishing the same may be understood more readily by reference to the following detailed description of embodiments and the accompanying drawings. However, the present disclosure may be embodied in many different forms, and should not be construed as being limited to the embodiments set forth herein. Rather, these embodiments are provided so that this disclosure will be through and complete and will fully convey the concept of the invention to those skilled in the art, and the present disclosure will only be defined by the appended claims. Like reference numbers designate like elements throughout the specification.

It will be understood that when an element or a layer is referred to as being “on” or “above” another element or layer, it can be directly on or above the other element or layer or intervening elements or layers may be present. In contrast, when an element is referred to as being “directly on” or “directly above”, there are no intervening elements or layers.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented, and, as such, the spatially relative descriptors used herein interpreted accordingly.

It will be understood that, although the terms “first”, “second”, etc. may be used herein to describe various elements, constituent elements and/or sections, the elements, constituent elements and/or sections should not be limited by these terms. These terms are only used to distinguish one element, constituent element, or section from another element, constituent element, or section. Thus, a first element, a first constituent element, or a first section discussed below should be termed a second element, a second constituent element, or a second section.

The terminology used herein is for the purpose of describing particular embodiments only and is not intended to be limiting of embodiments. As used herein, the singular forms, “a,” “an,” and “the” are intended to include the plural forms as well, unless the context clearly indicates otherwise. It will be further understood that the terms “comprises” and/or “comprising”, when used in this specification, specify the presence of stated features, steps, operations and/or components do not preclude the presence or addition of one or more features, steps, operations and/or components.

Unless otherwise defined, all terms (including technical and scientific terms) used herein have the same meaning as commonly understood by one of ordinary skill in the art to which the present invention belongs. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Exemplary embodiments of the present disclosure will hereinafter be described with reference to the accompanying drawings. Like reference numerals indicate like elements through the specification, and thus, detailed descriptions thereof will be omitted.

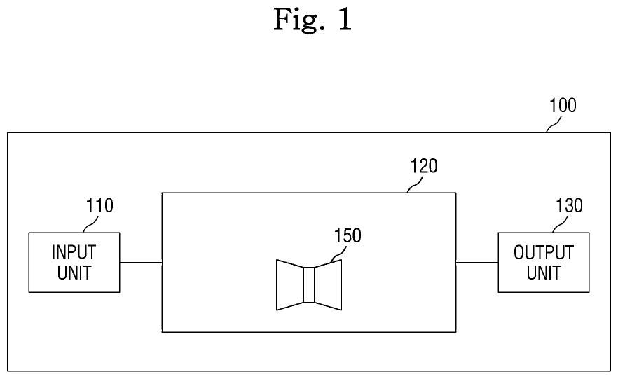

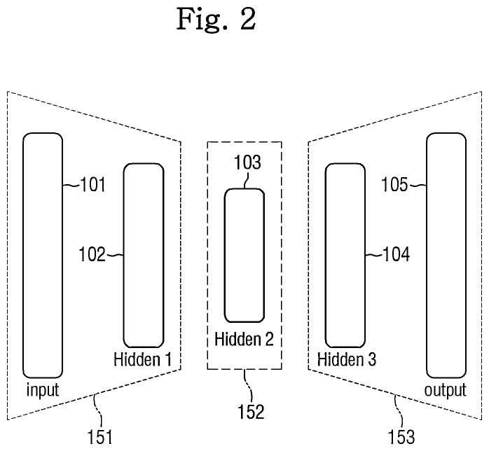

FIG. 1 is a block diagram of a semiconductor equipment diagnostic device according to an embodiment of the present disclosure, and FIG. 2 is a block diagram of a classifier included in a control unit of FIG. 1.

Referring to FIG. 1, a semiconductor equipment diagnostic device 100, which is a device connected to various semiconductor facilities for use in semiconductor fabrication processes and diagnoses whether each of the semiconductor facilities is normal or abnormal, includes an input unit 110, a control unit 120, and an output unit 130.

Specifically, the semiconductor equipment diagnostic device 100, which is an electronic device for performing an anomaly detection method that will be described later, may be, for example, a workstation, a computing device computer, a router, a personal computer (PC), a portable computer, a peer device, or another common network node, and typically includes many or all of the elements described in connection with a computer. The semiconductor equipment diagnostic device 100 may be connected to various semiconductor facilities via, for example, a local area network (LAN) or a larger network such as a wide area network (WAN), in a wired or wireless manner.

The input unit 110 may be connected to semiconductor equipment via a wired/wireless interface and may thus receive sensing data detected by multiple sensors included in the semiconductor equipment or recipe information regarding the semiconductor equipment. The input unit 110 may include various input means such as a keypad, a mouse, a universal serial bus (USB) port, an interface (e.g., Thunderbolt), a touch screen, or a button and may thus receive various user commands for the diagnosis of the semiconductor equipment.

The control unit 120 may include the classifier 150, which consists of an artificial intelligence neural network, and may control the overall operation of the semiconductor equipment diagnostic device 100 to learn and classify the sensing data received from the input unit 110 and the recipe information regarding the semiconductor equipment and thus to determine whether the semiconductor equipment is normal.

The control unit 120 may include at least one processor for data analysis and deep learning such as a central processing unit (CPU), a general-purpose graphics processing unit (GPGPU), or a tensor processing unit (TPU) of, for example, a computing device.

In connection with neural network learning, the control unit 120 may perform various operations such as processing input data for deep learning, extracting features from the input data, calculating error, and updating neural network weights via backpropagation by reading computer programs stored in a memory. Instructions for performing an anomaly detection method that will be described later may be stored in a memory. That is, the anomaly detection method may be performed when the at least one processor executes the stored instructions.

At least one of the CPU, the GPGPU, and the TPU of the control unit 120 may process the learning of a network function. For example, the CPU and the GPGPU may both process the learning of a network function and the classification of data with the use of the network function. The learning of a network function and the classification of data with the use of the network function may be processed using the processors of a plurality of computing devices.

Specifically, the control unit 120 may extract features from training data using the classifier 150, clusters the extracted features, reconstructs the training data based on the clustered features, and relearns the classifier 150 with the use of the reconstructed training data to create a plurality of relearned classifiers. Thereafter, the control unit 120 determines whether new input data is normal or abnormal.

Referring to FIG. 2, the classifier 150, which consists of an artificial intelligence neural network, may include an encoder 151, which includes an input layer 101 and a first hidden layer 102, feature space 152, which includes a middle hidden layer 103, and a decoder 153, which includes a third hidden layer 104 and an output layer 105.

For example, a deep neural network (DNN) may be used as the artificial intelligence neural network. The DNN includes not only an input layer and an output layer, but also multiple hidden layers, and the feature structure of data can be identified using the DNN. Examples of the DNN include a convolutional neural network (CNN), a recurrent neural network (RNN), an auto encoder, a generative adversarial network (GAN), a restricted Boltzmann machine (RBM), a deep brief network (DBM), a Q network, a U network, and a Siamese network. However, the DNN is merely exemplary, and the present disclosure is not limited thereto.

The classifier 150 will hereinafter be described as being, for example, an auto encoder. Referring to FIG. 2, the auto encoder, which is a type of artificial intelligence neural network for outputting output data similar to input data, may have an odd number of hidden layers, i.e., the first hidden layer 102, the middle hidden layer 103, and the third hidden layer 104, disposed between the input layer 101 and the output layer 105. The number of nodes of each of the layers of the auto encoder may decrease from the input layer 102 to the middle hidden layer 103 and may increase from the middle hidden layer 103 to the output layer 105. In the example of FIG. 2, the nodes of each dimension reduction layer are symmetrical to the nodes of each dimension restoration layer, but the present disclosure is not limited thereto. That is, the nodes of each dimension reduction layer may not necessarily be symmetrical to the nodes of each dimension restoration layer.

The auto encoder may perform nonlinear dimension reduction. The numbers of input layers 101 and output layers 105 may correspond to the number of sensors remained after the preprocessing of input data. The number of nodes of the first hidden layer 102 may gradually decrease away from the input layer 101.

If the number of nodes of the middle hidden layer 103 is too small, a sufficient amount of data may not be able to be transmitted. Thus, the number of nodes of the middle hidden layer 103 may be maintained to be, for example, at least half the number of nodes of the input layer 101.

The output unit 130 may be connected to the control unit 120 and may display whether the semiconductor equipment diagnosed by the control unit 120 is normal or abnormal. The output unit 130 may include various output means such as, for example, a monitor or a touch screen, and may thus display the progress of the diagnosis of semiconductor equipment and whether the semiconductor equipment is normal or abnormal.

By using the semiconductor equipment diagnostic device 100, particularly, the classifier 150, features can be extracted from training data and can be clustered, the training data can be reconstructed based on the clustered features, and a determination can be made as to whether new input data is normal or abnormal based on the reconstructed training data.

The semiconductor equipment diagnostic device 100 determines whether each of a variety of semiconductor equipment is normal or abnormal, using an auto encoder learned for each cluster of features. That is, the semiconductor equipment diagnostic device 100 does not use a diagnostic model for each recipe. Accordingly, the number of diagnostic models can be reduced, and the amount of computing resources and time consumed for artificial intelligence learning can be considerably reduced.

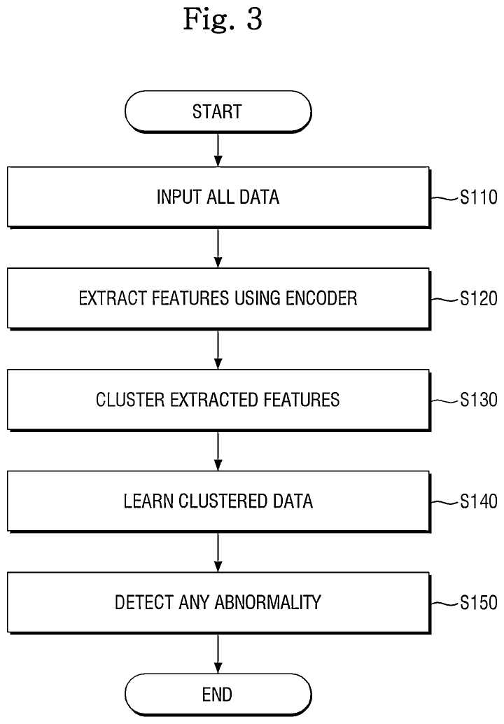

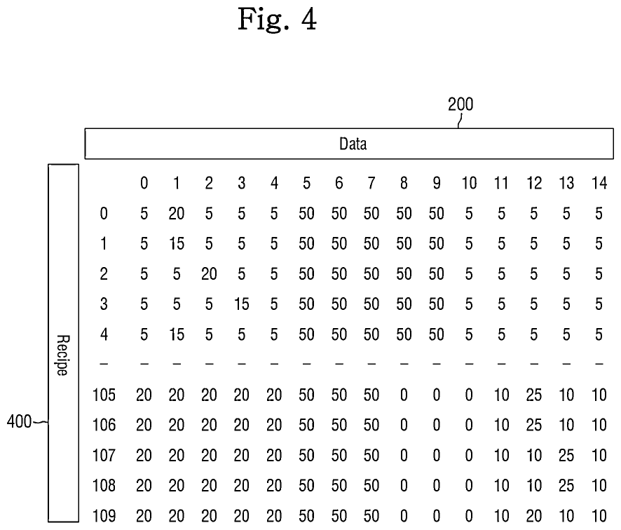

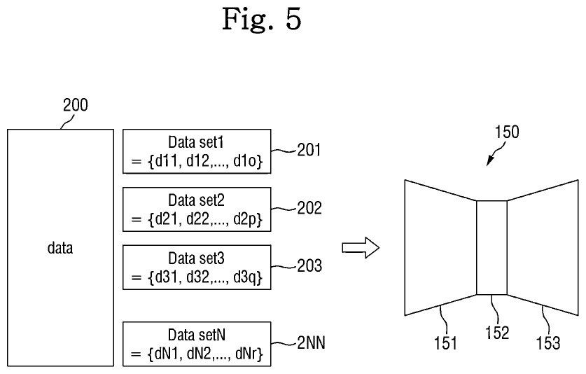

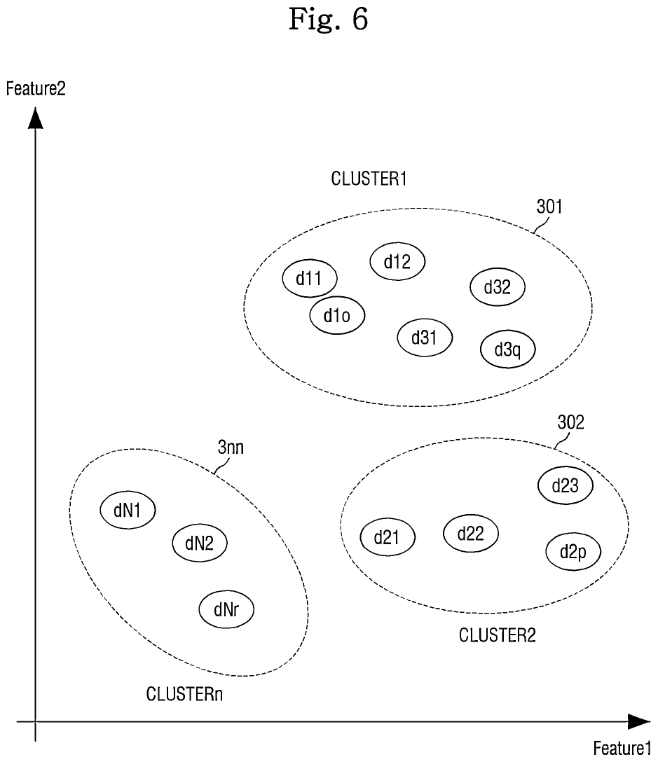

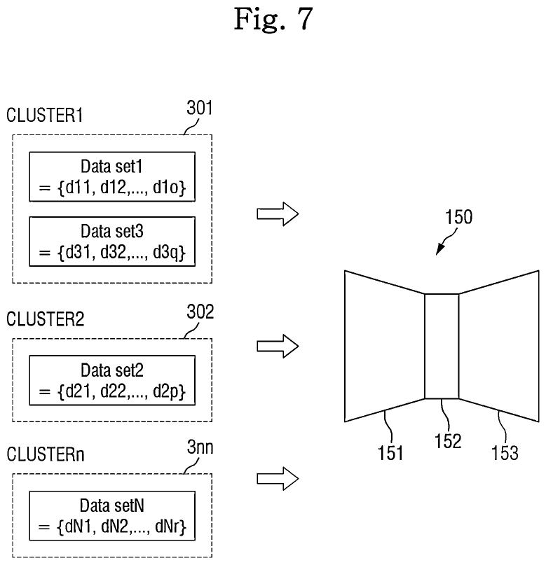

A semiconductor equipment diagnostic method using the semiconductor equipment diagnostic apparatus according to an embodiment of the present disclosure will hereinafter be described with reference to FIGS. 3 through 7. FIG. 3 is a flowchart illustrating a semiconductor equipment diagnostic method using the semiconductor equipment diagnostic apparatus according to an embodiment of the present disclosure, FIG. 4 illustrates data and a recipe processed by the semiconductor equipment diagnostic method of FIG. 3, FIG. 5 illustrates how to input data in the semiconductor equipment diagnostic method of FIG. 3, FIG. 6 illustrates how to cluster data in the semiconductor equipment diagnostic method of FIG. 3, and FIG. 7 illustrates how to process clustered data in the semiconductor equipment diagnostic method of FIG. 3.

Referring to FIG. 3, the control unit 120 receives input data from each semiconductor equipment connected to the semiconductor equipment diagnostic device 100 in a wired or wireless manner, via the input unit 110 (S110).

Specifically, the input data is training data and may be classified into a plurality of first subsets. For example, the input data may be classified into the first subsets in accordance with a predefined criterion (e.g., the type of recipes, equipment, or sensors). The input data will hereinafter be described as being classified into the first subsets depending on the type of recipe.

Referring to FIG. 4, data 200 and a recipe 200 may have a relationship with each other. The data 200 may include sensor data obtained by each semiconductor equipment, image data obtained from each semiconductor equipment, and operation parameters for each semiconductor equipment, and the recipe 400 may include settings for an operation of each semiconductor equipment, related to the data 200, such as, for example, how to change the wavelength of laser light to be applied during a lithography process.

The recipe 400 may have any electronic format such as a general text file format, an extensible markup language (XML) file format, and may include various parameters that can be set to different values, such as, for example, the sequence of processes to be performed on a semiconductor wafer, source power, bias power, a process gas flow, and process gas pressure.

Referring to FIG. 5, the data 200 may consist of a plurality of training data sets (201, 202, 203, . . . , and 2 NN), which correspond to the first subsets.

When there is a change in the recipe 400, sensor data obtained after the change in the recipe 400 may be included in a different training data set than sensor data obtained before the change in the recipe 400. In a general operation of semiconductor equipment, there may be multiple types of normal data due to, for example, a change in a manufacturing method over time.

The training data sets (201, 202, 203, . . . , and 2 NN) may include training data grouped by a predefined criterion in accordance with, for example, a change in a manufacturing method. In the case of a semiconductor production process, different normal data may be acquired for different recipes. That is, data acquired by different recipes during production may differ from one another, but may all be normal data. The training data sets (201, 202, 203, . . . , and 2 NN) may include different types of training data. The training data sets (201, 202, 203, . . . , and 2 NN) may be grouped by a predetermined criterion such as, for example, a creation time interval, a domain, or a recipe in a process.

However, the training data sets (201, 202, 203, . . . , and 2 NN) are merely exemplary, and the present disclosure is not limited thereto.

Referring to FIG. 3, after S110, the control unit 120 extracts features using the classifier 150 (hereinafter, the first classifier 150) or the encoder 151 (S120).

Specifically, the control unit 120 learns the first classifier 150 using a plurality of training data. Thereafter, features are extracted from the plurality of training data by computing the plurality of training data with the encoder 151 of the first classifier 150. To this end, the control unit 120 inputs data received by the input layer 101 of the encoder 151 and performs dimension reduction on the input data via the first hidden layer 102. That is, the control unit 120 may perform a convolution operation via the first hidden layer 102, using, for example, a filter. The convolution operation may be performed using a filter, as indicated by Equation (1):

$${net}_{mn}^{l} = {\sum }_{i = 0}^{{size}^{l} - 1} {\sum }_{j = 0}^{{size}^{l} - 1} ( {O}_{m + i , n + j}^{l - 1} … {w}_{i , j}^{l} + {b}^{l} ) \qquad ( 1 )$$

$$⊳ {f}_{c} = Conv ( {O}^{l - 1} , {w}^{l} , {I}_{n} , {l}_{a} ) = {net}_{{I}_{n} , {l}_{a}}^{l}$$

where l denotes the first hidden layer 102, size¹ denotes the size of the first hidden layer 102, Iₙ denotes the number of data input to the input layer 101, Iₐ denotes the number of labels, O denotes an output convolution layer, w denotes a weight, and b denotes bias.

Data processed by the convolution operation may be substituted into an activation function and may thereby be computed.

A sigmoid function or a ReLu function may be used as the activation function.

The control unit 120 performs a pooling operation using an output value obtained using the activation function.

Specifically, the pooling operation is for reducing the size of the dimension of data, particularly, the vertical and horizontal sizes of data. The pooling operation may use various parameters such as average, median, maximum, and minimum, and max pooling may be used as the pooling operation. By using max pooling, maximum values can be extracted from a limited region of image data, noise can be removed from data, and overfitting can be prevented during the reduction of data.

Max pooling may be performed, as indicated by Equation (2):

$$Pool ( x , i , j ) = \frac{{\sum }_{m = 1}^{{size}^{l}} {\sum }_{m = 1}^{{size}^{l}} {x}_{{size}^{l} \times ( i - 1 ) + m , {size}^{l} \times ( j - 1 ) + n}^{l - 1}}{{size}^{l} \times {size}^{l}} , \qquad ( 2 )$$

$$⊳ {f}_{p} = Pool ( {f}_{c} , {I}_{m} , {I}_{a} )$$

where x denotes an input matrix for the pooling operation, l denotes a layer of the pooling operation, i denotes a row of the input matrix x, j denotes a column of the input matrix x, size¹ denotes the size of the layer l of the pooling operation, Iₘ denotes the number of data input to the layer l of the pooling operation, and Iₐ denotes the number of labels.

After the pooling operation, the control unit 120 calculates a loss value using values obtained by the pooling operation and a predetermined target output value.

Specifically, the loss value may be calculated using Mean Squared Logarithmic Error (MSLE), Root MSLE (RMSLE), and symmetric Mean Absolute Percentage Error (sMAPE), as indicated by Equations (3) through (5) below, and the predetermined target output value may be ground truth (GT).

Here, the GT may be a value obtained by performing max pooling based on a convolution operation value obtained by a convolution operation via the first hidden layer 102.

$$M S L E = \frac{1}{N} {\sum }_{i = 0}^{N} {( log ( {y}_{i} + 1 ) - log ( {\hat{y}}_{i} + 1 ) )}^{2} ; \qquad ( 3 )$$

$$R M S L E = \sqrt{\frac{1}{N} {\sum }_{i = 0}^{N} {( log ( {y}_{i} + 1 ) - log ( {\hat{y}}_{i} + 1 ) )}^{2}} . \qquad ( 4 ) ;$$

$$and$$

$$s M A P E = \frac{100 \%}{n} {\sum }_{i = 1}^{N} ( \frac{\vert {y}_{i} - {\hat{y}}_{i} \vert}{\vert {y}_{i} \vert + \vert {\hat{y}}_{i} \vert} ) \qquad ( 5 )$$

where yᵢ denotes a pooling operation value for the pooling operation, and ŷᵢ denotes the predetermined target output value.

In this manner, features are extracted from the data 200 via the middle hidden layer 103 of the feature space 152.

Thereafter, referring to FIG. 3, a plurality of training data are clustered based on the extracted features (S130). As a result, the plurality of training data are reconstructed into a plurality of second subsets.

Specifically, features of data may be distributed in the feature space 152, as illustrated in FIG. 6, and the control unit 120 may group the features into multiple clusters. That is, the control unit 120 may create the multiple clusters. As features correspond one-to-one to their respective data, data (i.e., training data) may also be clustered by clustering their respective features. Accordingly, the plurality of training data may be classified into the second subsets. Each group of clustered data may be referred to as a second subset.

The features distributed in the features pace 152 may be clustered based on the distance therebetween, but the present disclosure is not limited thereto.

The clustering of the features distributed in the features pace 152 may be performed to minimize an objective function J, and the objective function J may be defined by Equation (6):

$$J = {\sum }_{j = 1}^{k} {\sum }_{i = 1}^{n} {‖ {x}_{i}^{( j )} - {c}_{j} ‖}^{2} \qquad ( 6 )$$

where k denotes the number of clusters, n denotes the number of features, xᵢ^{(j)} denotes the coordinates of each of the features, and c 1 denotes the coordinates of each centroid.

To perform clustering based on the distance between the features distributed in the feature space 152, the control unit 120 may set initial centroids for the features distributed in the feature space 152.

The number of initial centroids may be the same as the number of clusters, i.e., k of Equation (6).

Thereafter, the control unit 120 measures the distances between the features and the k initial centroids and allocates the features to their respective closest initial centroid.

The control unit 120 calculates the mean distance of the features allocated to each of the initial centroids from the corresponding initial centroid, and updates the initial centroids using the results of the calculation.

By repeating these processes, the clustering of the features may be completed when the objective function J of Equation (6) is minimized, and a plurality of clusters (301, 302, . . . , and 3 nn) may be displayed, as illustrated in FIG. 6. Training data corresponding to the clustered features are as illustrated in FIG. 6. For example, referring to FIG. 6, a first cluster 301 may include data d11, d12, and d1o from a first training data set 201 and data d31, d32, and d3q from a third training data set 203. As the first and third training data sets 201 and 203 are for different recipes, but have similar features, the data d11, d12, and d1o and the data d31, d32, and d3q may be classified into the same cluster, i.e., the first cluster 301.

Referring to FIG. 3, after S130, the control unit 120 inputs data included in each of the clusters (301, 302, . . . , and 3 nn) (i.e., data included in the second subsets) to the first classifier 150 and learns the data included in each of the clusters (301, 302, . . . , and 3 nn) (S140).

Specifically, a plurality of second classifiers, which correspond to the second subsets, are learned. As the second subsets correspond one-to-one to the second classifiers, the number of second subsets and the number of second classifiers may be the same.

The second classifiers may be learned in various manners. In particular, the use of the final weight of the learned first classifier 150 helps reduce the amount of time that it takes to learn the second classifiers. That is, the result of the learning of the first classifier 150 may be transferred to the second classifiers.

For example, the first classifier 150 used in S120 may also be used as the second classifiers. That is, the final weight of the first classifier 150 may be used as the initial weight of the second classifiers. Thereafter, data corresponding to the second subsets may be input to each of the second classifiers and may be learned, thereby learning the second classifiers differently.

Alternatively, the result of the learning of the first classifier 150 may be transferred to only some of the second classifiers.

For example, the second classifiers may not be learned at the same time, and some of the second classifiers may be learned ahead of the other second classifiers. In this example, the final weight of the first classifier 150 may be set as the initial weight of the second classifiers to be learned first. Thereafter, the final weight of the second classifiers that are learned first may be set as the initial weight of the second classifiers to be learned next. The second classifiers have been described as being classified into two groups, i.e., a group of second classifiers to be learned first and a group of second classifiers to be learned later, but the present disclosure is not limited thereto. That is, the second classifiers may be classified into s groups (where s is a natural number of 3 or greater), in which case, the final weight of the first classifier 150 is set as the initial weight of the second classifiers to be learned first and the final weight of second classifiers that are learned may be set as the initial weight of second classifiers to be learned next.

Alternatively, the result of the learning of the first classifier 150 may not be transferred to the second classifiers. That is, the initial weight of the second classifiers may be set regardless of the result of the learning of the first classifier 150.

Referring to FIG. 3, after S140, the control unit 120 determines whether the input data is abnormal (S150).

Specifically, the input data is all input to the second classifiers that have been learned. If any one of the second classifiers determines that the input data is normal, the input data may be determined as being normal, and if the second classifiers all determine that the input data is abnormal, the input data may be determined as being abnormal.

An auto encoder may determine whether particular data is normal or abnormal based on the difference between input data and output data for the particular data, in consideration that the error between input data and output data for abnormal data is greater than the error between input data and output data for normal data.

In this manner, the control unit 120 may determine whether input data for various recipes is normal or abnormal and may display the result of the determination via the output unit 130.

The number of first subsets (i.e., the number of training data sets classified by recipe) is greater than the number of second subsets (i.e., the number of training data sets classified by feature) or the number of second classifiers. As the second subsets correspond one-to-one to the second classifiers, the number of second classifiers is the same as the number of second subsets.

As the input data is input to a relatively small number of second classifiers, less computing resources and learning time are required to determine whether the input data is normal or abnormal.

According to embodiments of the present application, the present application further provides an electronic device, a non-transitory computer-readable storage medium, and a computer program.

The electronic device is intended to represent various forms of digital computers, such as a laptop, a desktop, a workstation, a personal digital assistant (PDA), a server, a blade server, a mainframe computer, and other suitable computers. The electronic device may further represent various forms of mobile devices, such as a PDA, a cellular phone, a smartphone, a wearable device, and other similar computing devices. The components, their connections and relationships, and their functions shown herein are examples only, and are not intended to limit the implementation of the present application as described and/or required herein.

As already described above with FIG. 1, the electronic device may include one or more processors, a memory, an input unit, an output unit, and an interface for connecting the other members of the electronic device.

Various implementations of the systems and technologies described herein may be implemented in a digital electronic circuit system, an integrated circuit system, a field programmable gate array (FPGA), an application specific integrated circuit (ASIC), an application specific standard product (ASSP), a system-on-chip (SOC), a complex programmable logical device (CPLD), computer hardware, firmware, software, and combinations thereof. The various implementations may include: being implemented in one or more computer programs. The one or more computer programs may be executed and/or interpreted on a programmable system including at least one programmable processor. The programmable processor may be a special-purpose or general-purpose programmable processor, receive data and instructions from a storage system, at least one input apparatus and at least one output apparatus, and transmit the data and the instructions to the storage system, the at least one input apparatus and the at least one output apparatus.

Program code for implementing the method of the present application may be generated using any combination of one or more programming languages. The program code may be provided to a processor or controller of a general- or special-purpose computer (or other programmable data processing devices) so that when the program code is executed by the processor or controller, the functions/operations specified in a flowchart and/or block diagram are performed. The program code may run entirely or partly on a machine, run partly on the machine as an independent software package, run partly on a remote machine, or run on a remote machine or server.

In the present disclosure, a machine (or computer)-readable medium may be a tangible medium, which may contain or store a program used by the instruction execution system, apparatus, or device or a program used in combination with the instruction execution system, apparatus, or device. The machine-readable medium may be a machine-readable signal medium or a machine-readable storage medium. The machine-readable medium may include, but is not limited to, an electronic, magnetic, optical, electromagnetic, infrared, or semiconductor system, apparatus or device, or any suitable combination of thereof. The machine-readable storage media, for example, includes an electrical connection based on one or more wires, a portable computer disk, a hard drive, a random access memory (RAM), a read-only memory (ROM), an erasable programmable read-only memory (EPROM or a flash memory), an optical fiber, a portable compact disk read-only memory (CD-ROM), an optical storage device, a magnetic storage device, or any suitable combination of thereof.

To provide interaction with a user, the systems and technologies described here can be implemented on a computer. The computer has: a display apparatus (e.g., a cathode-ray tube (CRT) or liquid crystal display (LCD) monitor) for displaying information to the user; and a keyboard and a pointing apparatus (e.g., a mouse or trackball) through which the user may provide input for the computer. Other types of apparatuses may also be configured to provide interaction with the user. For example, a feedback provided for the user may be any form of sensory feedback (e.g., visual, auditory, or tactile feedback); and input from the user may be received in any form (including sound input, voice input, or tactile input).

The systems and technologies described herein can be implemented in a computing system including background components (e.g., as a data server), or a computing system including middleware components (e.g., an application server), or a computing system including front-end components (e.g., a user computer with a graphical user interface or web browser through which the user can interact with the implementations of the systems and technologies described here), or a computing system including any combination of such background components, middleware components or front-end components. The components of the system can be connected to each other through digital data communication in any form or medium (for example, a communication network). Examples of the communication network include: a local area network (LAN), a wide area network (WAN), and the Internet.

The computer system may include a client and a server. The client and the server are generally far away from each other and generally interact via the communication network. A relationship between the client and the server is generated through computer programs that run on a corresponding computer and have a client-server relationship with each other. The server may be a cloud server, also known as a cloud computing server or cloud host, which is a host product in the cloud computing service system to solve the problems of difficult management and weak business scalability in the conventional physical host and a virtual private server (VPS) service. The server may be classified as a server of a distributed system or a server combined with a blockchain.

Although embodiments of the present invention have been described with reference to the above and the accompanying drawings, it will be appreciated by those of ordinary skill in the art that the present invention can be embodied in other specific forms without departing from its essential character. The embodiments described above should therefore be considered in all respects to be illustrative and not restrictive.

What is claimed is:

1. An anomaly detection method comprising:
learning a first classifier, which includes an encoder and a decoder, using a plurality of training data, which are classified into a plurality of first subsets;
extracting features from the plurality of training data by computing the plurality of training data with the encoder of the learned first classifier;
reconstructing the plurality of training data into a plurality of second subsets by clustering the plurality of training data based on the extracted features;
learning a plurality of second classifiers, which correspond to the plurality of second subsets, using the second subsets; and
detecting any abnormality in input data using the plurality of second classifiers.

2. The anomaly detection method of claim 1, wherein
the reconstructing the plurality of training data into the plurality of second subsets, comprises creating a plurality of feature clusters by clustering the extracted features and creating a plurality of second subsets, which correspond to the plurality of feature clusters, such that training data corresponding to features included in each of the plurality of feature clusters is allocated to a corresponding second subset.

3. The anomaly detection method of claim 2, wherein the clustering the extracted features, comprises clustering the extracted features based on locations of the extracted features in feature space.

4. The anomaly detection method of claim 1, wherein the learning the plurality of second classifiers, comprises reducing an amount of time that it takes to learn the plurality of second classifiers, by using a final weight of the learned first classifier.

5. The anomaly detection method of claim 4, wherein the learning the plurality of second classifiers, further comprises setting the final weight of the learned first classifier as an initial weight of the plurality of second classifiers.

6. The anomaly detection method of claim 4, wherein the learning the plurality of second classifiers, further comprises learning one of the plurality of second subsets first and then learning another one of the plurality of second subsets, setting the final weight of the learned first classifier as an initial weight of the former second subset, and setting a final weight of the former second subset as an initial weight of the latter second subset.

7. The anomaly detection method of claim 1, wherein the detecting any abnormality in the input data, comprises determining the input data as being normal if any one of the plurality of second classifiers determines that the input data is normal, and determining the input data as being abnormal if the plurality of second classifiers all determine that the input data is abnormal.

8. The anomaly detection method of claim 1, wherein the number of second classifiers is less than the number of first subsets.

9. The anomaly detection method of claim 1, wherein the first classifier or the plurality of second classifiers are configured as auto encoders.

10. An anomaly detection method comprising:
learning a classifier, which includes an encoder and a decoder, using a training data set, which includes a plurality of training data subsets;
extracting features for each training data of the training data set by computing each training data of the training data set with the encoder of the learned classifier;
reconstructing the training data subsets by clustering the extracted features based on locations of the extracted features in feature space and clustering each training data of the training data set based on the clustered features;
creating a plurality of relearned classifiers by relearning the learned classifier with the use of the reconstructed training data subsets; and
detecting any abnormality in input data using the plurality of relearned classifiers.

11. An electronic device comprising:
a processor; and
a memory connected to the processor,
wherein
the memory stores instructions that can be executed by the processor, and
the instructions are executed by the processor to execute the anomaly detection method of claim 1.
